(19) United States
(12) Patent Application Publication
(10) Pub. No.: US 2024/0241437 A1
(43) Pub. Date: Jul. 18, 2024

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Seol Hee LIM, Suwon-si (KR); Changsoo WOO, Suwon-si (KR); Young Keun KIM, Suwon-si (KR); Dong Wan RYU, Suwon-si (KR); Soobin LIM, Suwon-si (KR); Sukil KANG, Suwon-si (KR); Eunmi KANG, Suwon-si (KR)

(21) Appl. No.: 18/473,132

(22) Filed: Sep. 22, 2023

(30) Foreign Application Priority Data
Jan. 4, 2023 (KR) 10-2023-0001356

(51) Int. Cl. G03F 7/004; C07F 7/22

(52) U.S. Cl. CPC G03F 7/0042; C07F 7/2284

(57) ABSTRACT

A semiconductor photoresist composition and a method of forming patterns using the semiconductor photoresist composition are disclosed. The semiconductor photoresist composition may include an organotin compound represented by Chemical Formula 1 and a solvent.

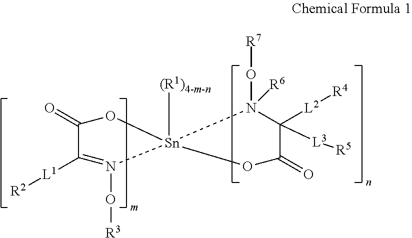

### CROSS-REFERENCE TO RELATED APPLICATION

This application claims priority to and the benefit of Korean Patent Application No. 10-2023-0001356, filed in the Korean Intellectual Property Office on Jan. 4, 2023, the entire content of which is incorporated herein by reference.

### BACKGROUND

### 1. Field

One or more embodiments of the present disclosure relate to a semiconductor photoresist composition and a method of forming patterns utilizing the same.

### 2. Description of the Related Art

EUV (extreme ultraviolet) lithography has been drawing much attention as one essential or desired technology for manufacturing a next generation semiconductor device. The EUV lithography is a pattern-forming technology utilizing an EUV ray having a wavelength of about 13.5 nm as an exposure light source. In EUV lithography, it is known that an extremely fine pattern (e.g., less than or equal to about 20 nm) may be formed in an exposure process during a manufacture of a semiconductor device.

The extreme ultraviolet (EUV) lithography is realized through development of compatible photoresists which can be performed at a spatial resolution of less than or equal to about 16 nm. Currently, efforts to overcome insufficient specifications of chemically amplified (CA) photoresists such as a resolution, a photospeed, and feature roughness (also referred to as a line edge roughness or LER) for the next generation device are being continuously made.

An intrinsic image blurring due to an acid catalyzed reaction in polymer-type or kind photoresists limits a resolution in small feature sizes, which has been well known in electron beam (e-beam) lithography for a long time. The chemically amplified (CA) photoresists are designed for high sensitivity, but because their typical elemental composition reduces light absorbance of the photoresists at a wavelength of about 13.5 nm and thus decreases their sensitivity, the chemically amplified (CA) photoresists may partially have more difficulties under an EUV exposure.

In addition, the CA photoresists may also have issues in making the small feature sizes due to roughness issues. The line edge roughness (LER) of the CA photoresists experimentally turns out to be increased, as a photospeed is decreased, partially due to an essence of acid catalyst processes. Accordingly, a novel high-performance photoresist is required and/or desired in a semiconductor industry because of these defects and problems of the CA photoresists.

To overcome the aforementioned drawbacks of the chemically amplified (CA) organic photosensitive composition, an inorganic photosensitive composition has been researched. The inorganic photosensitive composition is mainly utilized for negative tone patterning having resistance against removal by a developer composition due to chemical modification through nonchemical amplification mechanism. The inorganic composition contains an inorganic element having a higher EUV absorption rate than hydrocarbon, and thus may secure sensitivity through the nonchemical amplification mechanism and is less sensitive about (or to) a stochastic effect and thus can have low line edge roughness and the small number of defects.

Inorganic photoresists based on peroxopolyacids of tungsten mixed with niobium, titanium, and/or tantalum have been reported and utilized as radiation sensitive materials for patterning.

These materials are effective for patterning large pitches for a bilayer configuration for far ultraviolet (deep UV), X-ray, and electron beam sources. More recently, when cationic hafnium metal oxide sulfate (HfSOx) materials along with a peroxo complexing agent is utilized to image a 15 nm half-pitch (HP) through projection EUV exposure, desired performance has been obtained. This system appears to exhibit the highest performance of a non-CA photoresist and has a practical photospeed near to a requirement for an EUV photoresist. However, the hafnium metal oxide sulfate materials having the peroxo complexing agent have a few practical drawbacks. First, these materials are coated in a mixture of corrosive sulfuric acid/hydrogen peroxide and have insufficient shelf-life stability. Second, a structural change thereof for performance improvement as a composite mixture is not easy. Third, development is performed in a TMAH (tetramethylammonium hydroxide) solution at an extremely high concentration of about 25 wt % and/or the like.

In recent years, active research has been conducted on molecules containing tin that have excellent or suitable absorption of extreme ultraviolet rays. As for an organotin polymer among them, an alkyl ligand is dissociated by light absorption or secondary electrons produced thereby and cross-linked with adjacent chains through an oxo bond and thus enables the negative tone patterning that may not be removed by an organic developing solution. The organotin polymer exhibits significantly improved sensitivity as well as maintains a suitable resolution and line edge roughness, but the patterning characteristics should or need to be further improved for commercial availability.

### SUMMARY

One or more aspects of embodiments of the present disclosure are directed toward a semiconductor photoresist composition with improved storage stability and coating properties.

One or more aspects of embodiments of the present disclosure are directed toward a method of forming patterns utilizing the semiconductor photoresist composition.

Additional aspects will be set forth in part in the description which follows and, in part, will be apparent from the description, or may be learned by practice of the presented embodiments of the disclosure.

According to one or more embodiments, a semiconductor photoresist composition (e.g., a photoresist composition) may include an organotin compound represented by Chemical Formula 1 and a solvent.

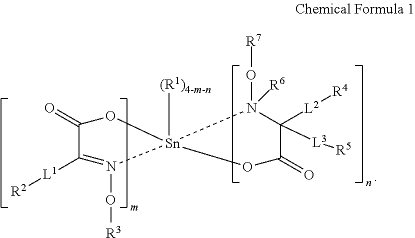

In Chemical Formula 1,

R¹ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof,

R², R⁴, and R⁵ may each independently be hydrogen, a cyano group, a sulfonyl group, a thiol group, a sulfide group, a thioketone group, a ketone group, an aldehyde group, a hydroxy group, an amine group, an amide group, a halogen, a substituted or unsubstituted C1 to C20 alkyl group, a substituted or unsubstituted C1 to C20 alkoxy group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, a substituted or unsubstituted C2 to C30 heterocyclic group, or a combination thereof,

R³, R⁶, and R⁷ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof,

L¹ to L³ may each independently be a single bond, a substituted or unsubstituted divalent C1 to C20 saturated aliphatic hydrocarbon group, a substituted or unsubstituted divalent C3 to C20 saturated or unsaturated alicyclic hydrocarbon group, a substituted or unsubstituted divalent C2 to C20 unsaturated aliphatic hydrocarbon group (including at least one of a double bond or a triple bond), a substituted or unsubstituted divalent C6 to C20 aromatic hydrocarbon group, —C(═O)—, —C(═S)—, or a combination thereof, m and n may each independently be one of integers from 0 to 3, and

m+n is an integer of greater than or equal to 1.

In one or more embodiments, Chemical Formula 1 may be represented by Chemical Formula 2 or Chemical Formula 3.

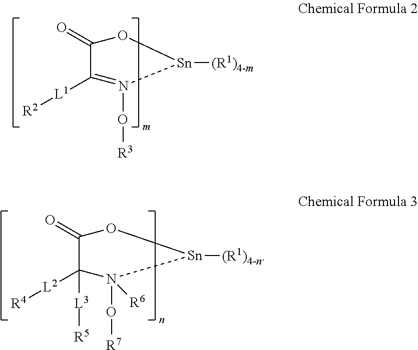

In Chemical Formula 2 and Chemical Formula 3,

R¹ to R⁷ and L¹ to L³ are each the same as defined above, and

m and n may each independently be one of integers from 1 to 3.

In one or more embodiments, m and n may each independently be an integer of 1 or 2.

In one or more embodiments, Chemical Formula 2 may be represented by Chemical Formula 2-1.

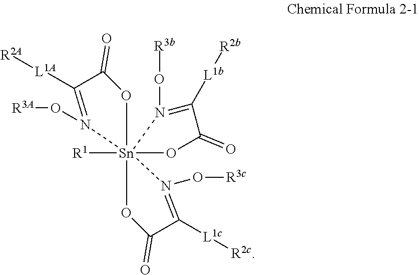

In Chemical Formula 2-1,

R¹ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof,

R^{2a}, R^{2b}, and R^{2c} may each independently be hydrogen, a cyano group, a sulfonyl group, a thiol group, a sulfide group, a thioketone group, a ketone group, an aldehyde group, a hydroxy group, an amine group, an amide group, a halogen, a substituted or unsubstituted C1 to C20 alkyl group, a substituted or unsubstituted C1 to C20 alkoxy group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, a substituted or unsubstituted C2 to C30 heterocyclic group, or a combination thereof,

R^{3a}, R^{3b}, and R^{3c} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof, and

L^{1a}, L^{1b}, and L^{1c} may each independently be a single bond, a substituted or unsubstituted divalent C1 to C20 saturated aliphatic hydrocarbon group, a substituted or unsubstituted divalent C3 to C20 saturated or unsaturated alicyclic hydrocarbon group, a substituted or unsubstituted divalent C2 to C20 unsaturated aliphatic hydrocarbon group (including at least one of a double bond or a triple bond), a substituted or unsubstituted divalent C6 to C20 aromatic hydrocarbon group, —C(═O)—, —C(═S)—, or a combination thereof.

In one or more embodiments, Chemical Formula 3 may be represented by Chemical Formula 3-1.

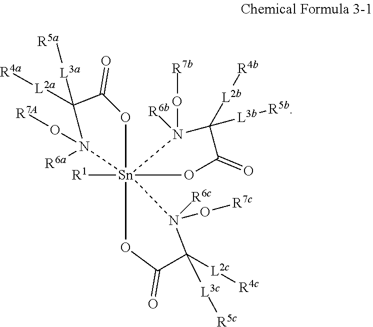

In Chemical Formula 3-1,

R¹ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof,

R^{4a}, R^{4b}, R^{4c}, R^{5a}, R^{5b}, and R^{5c} may each independently be hydrogen, a cyano group, a sulfonyl group, a thiol group, a sulfide group, a thioketone group, a ketone group, an aldehyde group, a hydroxy group, an amine group, an amide group, a halogen, a substituted or unsubstituted C1 to C20 alkyl group, a substituted or unsubstituted C1 to C20 alkoxy group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, a substituted or unsubstituted C2 to C30 heterocyclic group, or a combination thereof,

R^{6a}, R^{6b}, R^{6c}, R^{7a}, R^{7b}, and R^{7c} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof, and

L²a, L³a, L²b, L³b, L²c, and L³c may each independently be a single bond, a substituted or unsubstituted divalent C1 to C20 saturated aliphatic hydrocarbon group, a substituted or unsubstituted divalent C3 to C20 saturated or unsaturated alicyclic hydrocarbon group, a substituted or unsubstituted divalent C2 to C20 unsaturated aliphatic hydrocarbon group (including at least one of a double bond or a triple bond), a substituted or unsubstituted divalent C6 to C20 aromatic hydrocarbon group, —C(═O)—, —C(═S)—, or a combination thereof.

In one or more embodiments, R¹ may be a substituted or unsubstituted C1 to C20 alkyl group.

In one or more embodiments, R², R⁴, and R⁵ may each independently be hydrogen, a cyano group, a sulfonyl group, a thiol group, a sulfide group, a thioketone group, a ketone group, an aldehyde group, a hydroxy group, an amine group, an amide group, a cyano group, halogen, a substituted or unsubstituted C1 to C20 alkyl group, a substituted or unsubstituted C6 to C30 aryl group, a substituted or unsubstituted C2 to C30 heterocyclic group, or a combination thereof.

In one or more embodiments, R², R⁴, and R⁵ may each independently be hydrogen, a cyano group, a sulfonyl group, a thiol group, a sulfide group, a thioketone group, a ketone group, an aldehyde group, a hydroxy group, an amine group, an amide group, a cyano group, a halogen, an n-propyl group, an n-butyl group, an n-pentyl group, an n-hexyl group, an n-heptyl group, an n-octyl group, an n-nonyl group, an n-decyl group, an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, a tert-decyl group, a substituted or unsubstituted phenyl group, a substituted or unsubstituted benzoxazolyl group, a substituted or unsubstituted thiazolyl group, a substituted or unsubstituted benzothiazolyl group, or a substituted or unsubstituted benzimidazolyl group.

In one or more embodiments, L¹ to L³ may each independently be a single bond, or a substituted or unsubstituted C1 to C20 alkylene group.

In one or more embodiments, the organotin compound may be one selected from compounds listed in Group 2.

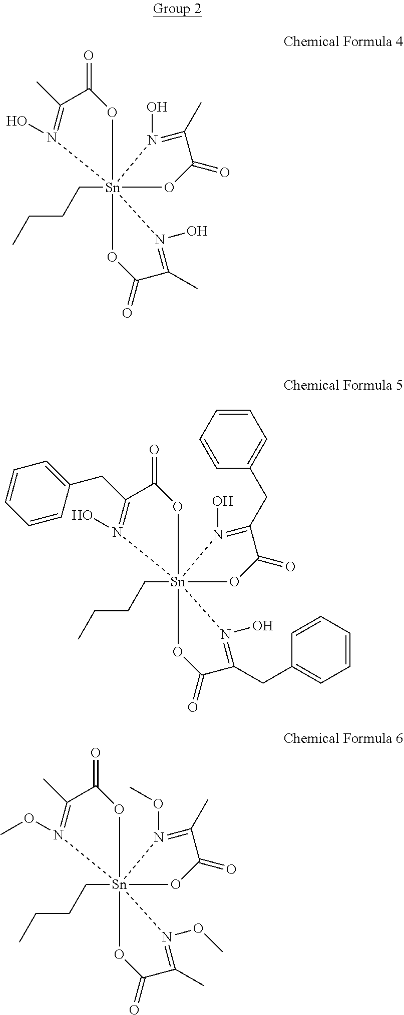

In one or more embodiments, based on 100 wt % of the semiconductor photoresist composition, the organotin compound may be included in an amount of about 1 wt % to about 30 wt %.

In one or more embodiments, the semiconductor photoresist composition may further include an additive, such as a surfactant, a crosslinking agent, a leveling agent, or a combination thereof.

According to one or more embodiments, a method of forming patterns may include forming an etching target layer on a substrate, coating the semiconductor photoresist composition on the etching target layer to form a photoresist layer, patterning the photoresist layer to form a photoresist pattern, and etching the etching target layer utilizing the photoresist pattern as an etching mask.

The photoresist pattern may be formed utilizing light in a wavelength of about 5 nm to about 150 nm.

In one or more embodiments, the method of forming patterns may further include providing a resist underlayer formed between the substrate and the photoresist layer.

The photoresist pattern may have a width (e.g., a line width) of about 5 nm to about 100 nm.

The semiconductor photoresist composition according to one or more embodiments may provide a photoresist pattern with improved sensitivity while maintaining line edge roughness.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 to 5 are each of cross-sectional views for illustrating a method of forming patterns utilizing a semiconductor photoresist composition according to one or more embodiments of the present disclosure.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

Hereinafter, the embodiments of the present disclosure will be described in more detail, referring to the accompanying drawings. However, in the description of the present disclosure, descriptions for already established functions or components will not be provided for clarifying the gist of the present disclosure.

In order to clearly describe the present disclosure, parts which are not related to the description are not provided for conciseness, and the same reference numeral refers to the same or like components, throughout the present disclosure. In some embodiments, because the size and the thickness of each component shown in the drawing are optionally represented for convenience of the description, the present disclosure is not necessarily limited to the illustration.

In the drawings, the thickness of layers, films, panels, regions, etc., may be exaggerated for clarity. In the drawings, the thickness of a part of layers or regions, etc., may be exaggerated for clarity. It will be understood that when an element such as a layer, film, region, or substrate is referred to as being “on” another element, it may be directly on the other element or intervening elements may also be present. In contrast, when an element is referred to as being “directly on” another element, there are no intervening elements present.

As utilized herein, “substituted” refers to replacement of a hydrogen by deuterium, a halogen, a hydroxy group, a cyano group, a sulfonyl group, a thiol group, a sulfide group, a thioketone group, a ketone group, an aldehyde group, amide group, a nitro group, —NRR′(wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a combination thereof.

“Unsubstituted” may refer to non-replacement of a hydrogen by another substituent and remaining of the hydrogen.

As utilized herein, when a definition is not otherwise provided, “alkyl group” refers to a linear or branched aliphatic hydrocarbon group. The alkyl group may be “a saturated alkyl group” without any double bond or triple bond.

The alkyl group may be a C1 to C10 alkyl group. For example, the alkyl group may be a C1 to C8 alkyl group, a C1 to C7 alkyl group, a C1 to C6 alkyl group, a C1 to C5 alkyl group, or a C1 to C4 alkyl group. For example, the C1 to C4 alkyl group may be a methyl group, an ethyl group, a propyl group, an isopropyl group, an n-butyl group, an isobutyl group, a sec-butyl group, a tert-butyl group, or a 2,2-dimethylpropyl group.

As utilized herein, when a definition is not otherwise provided, “cycloalkyl group” may refer to a monovalent cyclic aliphatic hydrocarbon group.

The cycloalkyl group may be a C3 to C10 cycloalkyl group, for example, a C3 to C8 cycloalkyl group, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but is not limited thereto.

As utilized herein, “aryl group” may refer to a substituent in which all atoms in the cyclic substituent have a p-orbital and these p-orbitals are conjugated and may include a monocyclic or fused ring polycyclic functional group (i.e., rings sharing adjacent pairs of carbon atoms).

As utilized herein, unless otherwise defined, “alkenyl group” may refer to an aliphatic unsaturated alkenyl group including at least one double bond as a linear or branched aliphatic hydrocarbon group.

As utilized herein, unless otherwise defined, “alkynyl group” may refer to an aliphatic unsaturated alkynyl group including at least one triple bond as a linear or branched aliphatic hydrocarbon group.

In the chemical formulas described herein, t-Bu may refer to a tert-butyl group.

Hereinafter, a semiconductor photoresist composition according to one or more embodiments will be described in more detail.

In one or more embodiments of the present disclosure, the semiconductor photoresist composition may include an organotin compound represented by Chemical Formula 1 and a solvent.

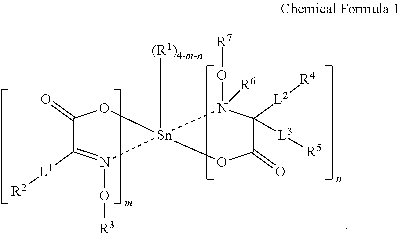

In Chemical Formula 1,

R¹ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof,

R², R⁴, and R⁵ may each independently be hydrogen, a cyano group, a sulfonyl group, a thiol group, a sulfide group, a thioketone group, a ketone group, an aldehyde group, a hydroxy group, an amine group, an amide group, a halogen, a substituted or unsubstituted C1 to C20 alkyl group, a substituted or unsubstituted C1 to C20 alkoxy group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, a substituted or unsubstituted C2 to C30 heterocyclic group, or a combination thereof,

R³, R⁶, and R⁷ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof,

L¹ to L³ may each independently be a single bond, a substituted or unsubstituted divalent C1 to C20 saturated aliphatic hydrocarbon group, a substituted or unsubstituted divalent C3 to C20 saturated or unsaturated alicyclic hydrocarbon group, a substituted or unsubstituted divalent C2 to C20 unsaturated aliphatic hydrocarbon group (including at least one of a double bond or a triple bond), a substituted or unsubstituted divalent C6 to C20 aromatic hydrocarbon group, —C(═O)—, —C(═S)—, or a combination thereof,

m and n may each independently be one of integers from 0 to 3, and

m+n may be an integer of greater than or equal to 1.

The organotin compound may include at least one bidentate ligand directly bonded to Sn and has at least two coordination sites, so that unshared electron pairs may induce intramolecular as well as intermolecular coordination bonds, which is advantageous for forming an amorphous matrix.

In some embodiments, compared with a quadrivalent coordinated cluster form, a form of satisfying the coordination number of Sn and structurally masking Sn atoms due to the additional coordination bonds may be obtained, thereby improving stability to moisture, and in addition, because aggregation due to nucleation by oxygen included in the cluster is prevented or reduced, long-term storage stability may also be increased. Accordingly, defects may be effectively reduced in the coating process, which may affect coating stability.

In some embodiments, compared with an organotin compound including a monodentate ligand alone, intermolecular or intramolecular bonding may be strengthened, thereby improving a bonding force with the substrate and resultantly, improving thin film stability.

In some embodiments, as the aggregation due to the nucleation is prevented or reduced, the spin coating in an amorphous form without utilizing an additive may be performed, thereby improving sensitivity and coating properties.

In one or more embodiments, Chemical Formula 1 may be represented by Chemical Formula 2 or Chemical Formula 3.

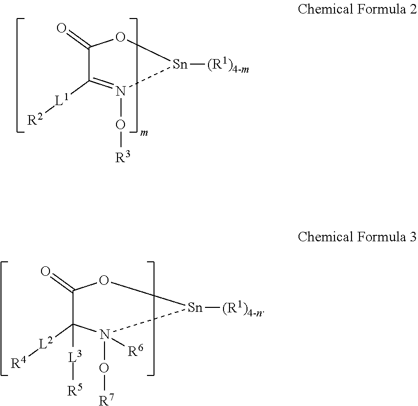

In Chemical Formula 2 and Chemical Formula 3,

R¹ to R⁷ and L¹ to L³ are each the same as described above, and

m and n may each independently be one selected from among integers from 1 to 3.

In one or more embodiments, m and n may each independently be an integer of 1 or 2.

In one or more embodiments, Chemical Formula 2 may be represented by Chemical Formula 2-1.

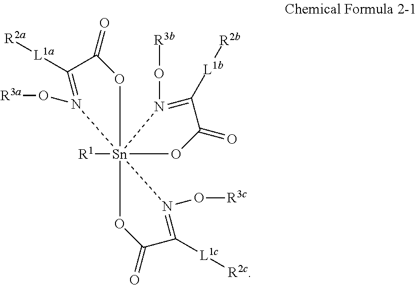

In Chemical Formula 2-1,

R¹ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof,

R^{2a}, R^{2b}, and R^{2c} may each independently be hydrogen, a cyano group, a sulfonyl group, a thiol group, a sulfide group, a thioketone group, a ketone group, an aldehyde group, a hydroxy group, an amine group, an amide group, a halogen, a substituted or unsubstituted C1 to C20 alkyl group, a substituted or unsubstituted C1 to C20 alkoxy group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, a substituted or unsubstituted C2 to C30 heterocyclic group, or a combination thereof,

R^{3a}, R^{3b}, and R^{3c} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof, and

L¹a, L¹b, and L^{1c} may each independently be a single bond, a substituted or unsubstituted divalent C1 to C20 saturated aliphatic hydrocarbon group, a substituted or unsubstituted divalent C3 to C20 saturated or unsaturated alicyclic hydrocarbon group, a substituted or unsubstituted divalent C2 to C20 unsaturated aliphatic hydrocarbon group including at least one a double bond or a triple bond, a substituted or unsubstituted divalent C6 to C20 aromatic hydrocarbon group, —C(═O)—, —C(═S)—, or a combination thereof.

In one or more embodiments, Chemical Formula 3 may be represented by Chemical Formula 3-1.

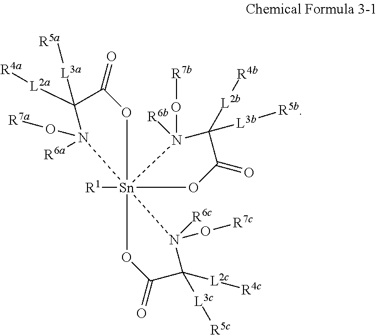

In Chemical Formula 3-1,

R¹ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof,

R^{4a}, R^{4b}, R^{4c}, R^{5a}, R^{5b}, and R^{5c} may each independently be hydrogen, a cyano group, a sulfonyl group, a thiol group, a sulfide group, a thioketone group, a ketone group, an aldehyde group, a hydroxy group, an amine group, an amide group, a halogen, a substituted or unsubstituted C1 to C20 alkyl group, a substituted or unsubstituted C1 to C20 alkoxy group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, a substituted or unsubstituted C2 to C30 heterocyclic group, or a combination thereof,

1 R^{6a}, R^{6b}, R^{6c}, R^{7a}, R^{7b}, and R^{7c} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof, and

L²a, L³a, L²b, L³b, L²c, and L³c may each independently be a single bond, a substituted or unsubstituted divalent C1 to C20 saturated aliphatic hydrocarbon group, a substituted or unsubstituted divalent C3 to C20 saturated or unsaturated alicyclic hydrocarbon group, a substituted or unsubstituted divalent C2 to C20 unsaturated aliphatic hydrocarbon group (including at least one of a double bond or a triple bond), a substituted or unsubstituted divalent C6 to C20 aromatic hydrocarbon group, —C(═O)—, —C(═S)—, or a combination thereof.

For example, in some embodiments, R¹ may be a substituted or unsubstituted C1 to C20 alkyl group.

In one or more embodiments, R¹ may be an n-propyl group, an n-butyl group, an n-pentyl group, an n-hexyl group, an n-heptyl group, an n-octyl group, an n-nonyl group, an n-decyl group, an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, or a tert-decyl group.

in one or more embodiments, R², R⁴, and R⁵ may each independently be hydrogen, a cyano group, a sulfonyl group, a thiol group, a sulfide group, a thioketone group, a ketone group, an aldehyde group, a hydroxy group, an amine group, an amide group, a cyano group, a halogen, a substituted or unsubstituted C1 to C20 alkyl group, a substituted or unsubstituted C6 to C30 aryl group, a substituted or unsubstituted C2 to C30 heterocyclic group, or a combination thereof.

In one or more embodiments, R², R⁴, and R⁵ may each independently be hydrogen, a cyano group, a sulfonyl group, a thiol group, a sulfide group, a thioketone group, a ketone group, an aldehyde group, a hydroxy group, an amine group, an amide group, a cyano group, a halogen, an n-propyl group, an n-butyl group, an n-pentyl group, an n-hexyl group, an n-heptyl group, an n-octyl group, an n-nonyl group, an n-decyl group, an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, a tert-decyl group, a substituted or unsubstituted phenyl group, a substituted or unsubstituted benzoxazolyl group, a substituted or unsubstituted thiazolyl group, a substituted or unsubstituted benzothiazolyl group, or a substituted or unsubstituted benzimidazolyl group.

In one or more embodiments, L¹ to L³ may each independently be a single bond or a substituted or unsubstituted C1 to C20 alkylene group.

In some embodiments, L¹ to L³ may each independently be a single bond, a substituted or unsubstituted methylene group, a substituted or unsubstituted ethylene group, or a substituted or unsubstituted propylene group.

In one or more embodiments, the organotin compound may be represented by Chemical Formula 2-1.

In one or more embodiments, the precursor of the bidentate ligand of the organotin compound may include a 2-hydroxyiminocarboxylate compound, a 2-methoxyiminocarboxylate compound, and/or the like, and may be at least one selected from compounds listed in Group 1.

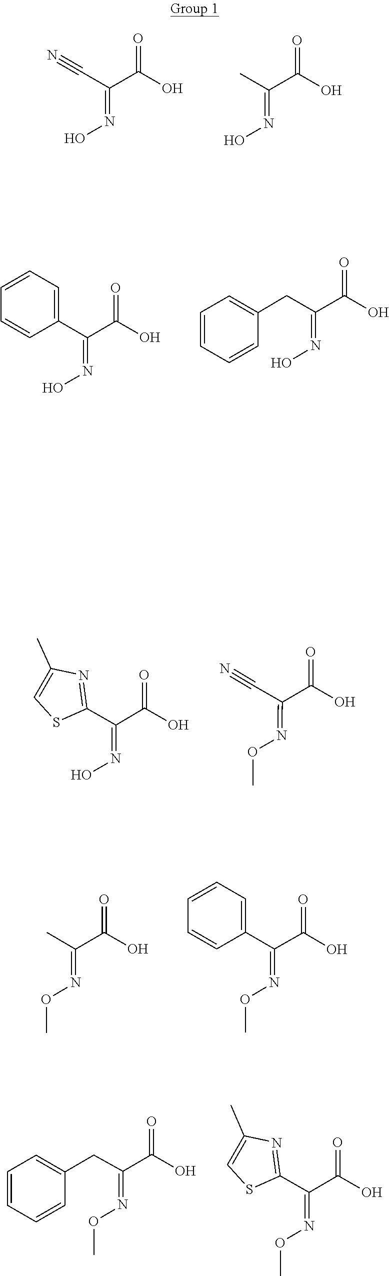

Non-limiting examples of the organotin compound may include compounds listed in Group 2.

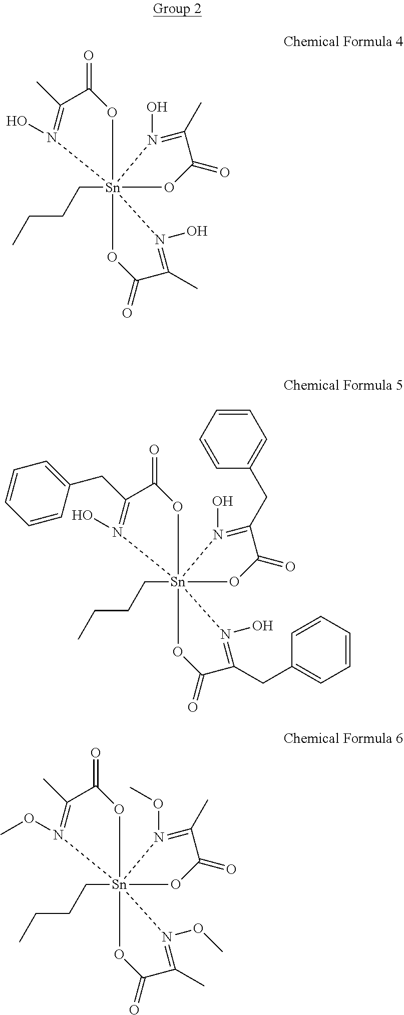

For example, in one or more embodiments, the organotin compound may be represented by Chemical Formula 2.

In some embodiments, the organotin compound may be represented by Chemical Formula 2-1.

The organotin compound may strongly absorb extreme ultraviolet light at about 13.5 nm and may have excellent or suitable sensitivity to light having high energy.

In the semiconductor photoresist composition according to one or more embodiments of the present disclosure, based on 100 wt % of the semiconductor photoresist composition, the organotin compound may be included in an amount of about 1 wt % to about 30 wt %, for example, about 1 wt % to about 25 wt %, for example, about 1 wt % to about 20 wt %, for example, about 1 wt % to about 15 wt %, for example, about 1 wt % to about 10 wt %, or, for example, about 1 wt % to about 5 wt %, but embodiments of the present disclosure are not limited thereto. When the organotin compound is included in an amount within the above ranges, storage stability and etch resistance of the semiconductor photoresist composition are improved, and resolution characteristics are improved.

As the semiconductor photoresist composition according to one or more embodiments of the present disclosure may have excellent or suitable sensitivity and pattern formability due to the aforementioned organotin compound.

The solvent included in the semiconductor photoresist composition according to one or more embodiments may be an organic solvent. The solvent may be, for example, aromatic compounds (e.g., xylene, toluene, etc.), alcohols (e.g., 4-methyl-2-pentanol, 4-methyl-2-propanol, 1-butanol, methanol, isopropyl alcohol, 1-propanol), ethers (e.g., anisole, tetrahydrofuran), esters (n-butyl acetate, propylene glycol monomethyl ether acetate, ethyl acetate, ethyl lactate), ketones (e.g., methyl ethyl ketone, 2-heptanone), or a mixture thereof, but embodiments of the present disclosure are not limited thereto.

In one or more embodiments, the semiconductor photoresist composition may further include a resin in addition to the organotin compound and the solvent.

The resin may be a phenol-based resin including one or more aromatic moieties selected from Group 3.

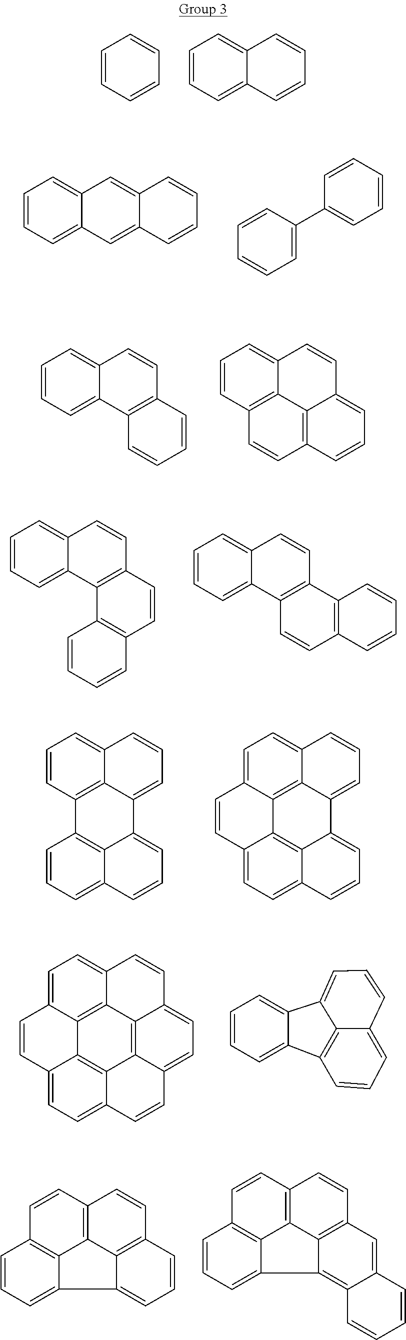

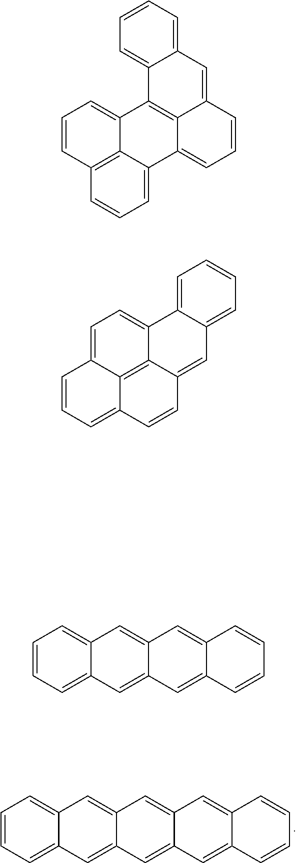

The resin may have a weight average molecular weight of about 500 to about 20,000.

The resin may be included in an amount of about 0.1 wt % to about 50 wt % based on a total amount of the semiconductor photoresist composition.

When the resin is included within the above amount range, the semiconductor photoresist composition may have excellent or suitable etch resistance and heat resistance.

In some embodiments, the semiconductor photoresist composition may be desirably composed of the aforementioned organotin compound, solvent, and resin. However, in some embodiments, the semiconductor photoresist composition may further include an additive as needed. Non-limiting examples of the additive may include a surfactant, a crosslinking agent, a leveling agent, organic acid, a quencher, or a combination thereof.

The surfactant may include, for example, an alkyl benzene sulfonate salt, an alkyl pyridinium salt, polyethylene glycol, a quaternary ammonium salt, or a combination thereof, but embodiments of the present disclosure are not limited thereto.

The crosslinking agent may be, for example, a melamine-based crosslinking agent, a substituted urea-based crosslinking agent, an acryl-based crosslinking agent, an epoxy-based crosslinking agent, and/or a polymer-based crosslinking agent, but embodiments of the present disclosure are not limited thereto. In one or more embodiments, it may be a crosslinking agent having at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, or methoxymethylated thiourea, and/or the like.

The leveling agent may be utilized for improving coating flatness during printing and may be a commercially available and suitable leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but embodiments of the present disclosure are not limited thereto.

The quencher may be diphenyl (p-tolyl) amine, methyl diphenyl amine, triphenyl amine, phenylenediamine, naphthylamine, diaminonaphthalene, or a combination thereof.

An amount of the additive(s) in the semiconductor photoresist composition may be controlled or selected depending on desired or suitable properties.

In some embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be, for example, a silane compound including a carbon-carbon unsaturated bond, such as vinyltrimethoxysilane, vinyltriethoxysilane, vinyl trichlorosilane, vinyltris(β-methoxyethoxy)silane, 3-methacryloxypropyltrimethoxysilane, 3-acryloxypropyltrimethoxysilane, p-styryl trimethoxysilane, 3-methacryloxypropylmethyldimethoxysilane, or 3-methacryloxypropylmethyl diethoxysilane; trimethoxy[3-(phenylamino)propyl]silane, and/or the like, but embodiments of the present disclosure are not limited thereto.

The semiconductor photoresist composition may be formed into a pattern having a high aspect ratio without a collapse. Accordingly, in order to form a fine pattern having a width of, for example, about 5 nm to about 100 nm, about 5 nm to about 80 nm, about 5 nm to about 70 nm, about 5 nm to about 50 nm, about 5 nm to about 40 nm, about 5 nm to about 30 nm, or about 5 nm to about 20 nm, the semiconductor photoresist composition may be utilized for a photoresist process utilizing light in a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Therefore, the semiconductor photoresist composition according to one or more embodiments of the present disclosure may be utilized to realize extreme ultraviolet lithography utilizing an EUV light source of a wavelength of about 13.5 nm.

According to one or more embodiments, a method of forming patterns utilizing the aforementioned semiconductor photoresist composition is provided. For example, the manufactured/formed pattern may be a photoresist pattern.

In one or more embodiments, the method of forming patterns may include forming an etching target layer on a substrate, coating the semiconductor photoresist composition on the etching target layer to form a photoresist layer, patterning the photoresist layer to form a photoresist pattern, and etching the etching target layer utilizing the photoresist pattern as an etching mask.

Hereinafter, a method of forming patterns utilizing the semiconductor photoresist composition will be described referring to FIGS. 1 to 5. FIGS. 1 to 5 are each of cross-sectional views for illustrating a method of forming patterns utilizing a semiconductor photoresist composition according to one or more embodiments of the present disclosure.

Referring to FIG. 1, a target for etching (e.g., an etching target layer) is prepared and provided. The target for etching may be a thin film 102 formed on a semiconductor substrate 100. Hereinafter, the target for etching is limited to the thin film 102. A whole surface of the thin film 102 is washed to remove impurities and/or the like remaining thereon. In one or more embodiments, the thin film 102 may be, for example, a silicon nitride layer, a polysilicon layer, or a silicon oxide layer.

Subsequently, a resist underlayer composition for forming a resist underlayer 104 is spin-coated on the surface of the washed/cleaned thin film 102. However, embodiments of the present disclosure are not limited thereto, and any suitable coating methods, for example, a spray coating, a dip coating, a knife edge coating, a printing method such as an inkjet printing and a screen printing, and/or the like may be utilized.

In some embodiments, the coating process of the resist underlayer may not be provided, but hereinafter, a process including a coating of the resist underlayer is described.

Then, the coated resist underlayer composition is dried and baked to form a resist underlayer 104 on the thin film 102. The baking may be performed at about 100 ºC to about 500° C., for example, about 100° C. to about 300° C.

The resist underlayer 104 is formed between the substrate 100 and a photoresist layer 106 and thus may prevent or reduce non-uniformity and pattern-forming capability of a photoresist line width when a ray reflected from the interface between the substrate 100 and the photoresist layer 106 or a hardmask between layers is scattered into an unintended photoresist region.

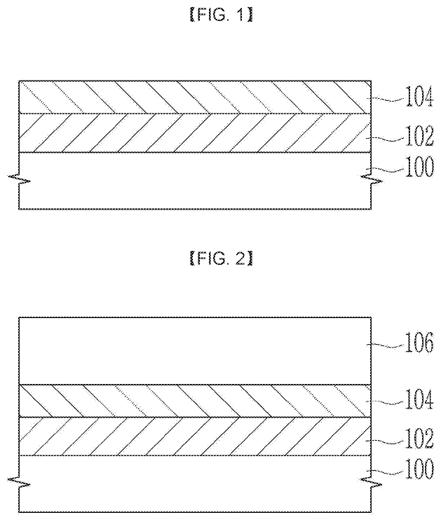

Referring to FIG. 2, a photoresist layer 106 is formed by coating the semiconductor photoresist composition on the resist underlayer 104. The photoresist layer 106 is obtained by coating the aforementioned semiconductor photoresist composition on the thin film 102 formed on the substrate 100 and then, curing it through a heat treatment.

In some embodiments, the formation of the photoresist layer by utilizing the semiconductor photoresist composition may include coating the semiconductor photoresist composition on the substrate 100 having the thin film 102 through spin coating, slit coating, inkjet printing, and/or the like and then, drying it to form the photoresist layer 106.

The semiconductor photoresist composition has already been illustrated in more detail and will not be illustrated again for conciseness.

Subsequently, the substrate 100 having the photoresist layer 106 is subjected to a first baking process. The first baking process may be performed at about 80° C. to about 120° C.

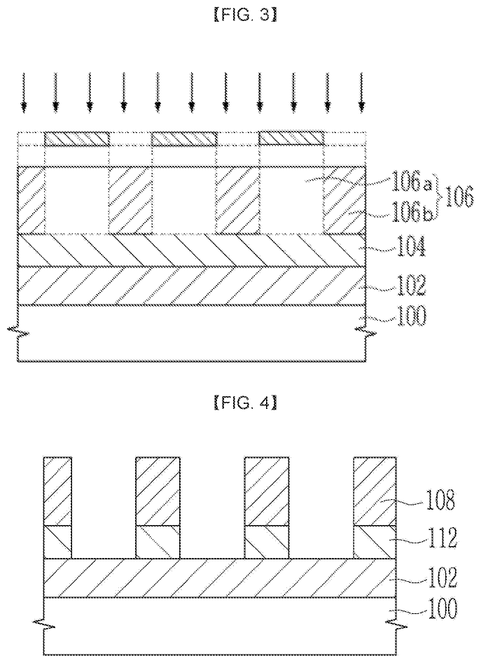

Referring to FIG. 3, the photoresist layer 106 may be selectively exposed.

For example, the exposure may utilize an activation radiation with light having a high energy wavelength such as EUV (extreme ultraviolet; a wavelength of about 13.5 nm), an E-Beam (an electron beam), and/or the like as well as a short wavelength such as an i-line (a wavelength of about 365 nm), a KrF excimer laser (a wavelength of about 248 nm), an ArF excimer laser (a wavelength of about 193 nm), and/or the like.

In one or more embodiments, light for the exposure may have a wavelength in a range of about 5 nm to about 150 nm or a high energy wavelength, for example, EUV (Extreme UltraViolet; a wavelength of about 13.5 nm), an E-Beam (an electron beam), and/or the like.

The exposed region 106b of the photoresist layer 106 has a different solubility from the non-exposed region 106a of the photoresist layer 106 by forming a polymer by a crosslinking reaction such as condensation between organometallic compounds.

Subsequently, the substrate 100 is subjected to a second baking process. The second baking process may be performed at a temperature of about 90° C. to about 200° C. The exposed region 106b of the photoresist layer 106 becomes substantially indissoluble regarding a developing solution due to the second baking process.

In FIG. 4, the non-exposed region 106a of the photoresist layer is dissolved and removed utilizing a developing solution to form a photoresist pattern 108. For example, the non-exposed region 106a of the photoresist layer is dissolved and removed by utilizing an organic solvent such as 2-heptanone and/or the like to complete the photoresist pattern 108 corresponding to a negative tone image.

As described above, a developing solution utilized in the method of forming patterns according to one or more embodiments may be an organic solvent. The organic solvent utilized as a developing solution in the method of forming patterns according to one or more embodiments may be, for example, ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, or a combination thereof.

However, the photoresist pattern according to one or more embodiments is not necessarily limited to the negative tone image but may be formed to have a positive tone image. In one or more embodiments, a developing agent utilized for forming the positive tone image may be a quaternary ammonium hydroxide composition such as tetraethylammonium hydroxide, tetrapropylammonium hydroxide, tetrabutylammonium hydroxide, or a combination thereof.

In one or more embodiments, exposure to light having a high energy such as EUV (Extreme UltraViolet; a wavelength of about 13.5 nm), an E-Beam (an electron beam), and/or the like as well as light having a wavelength such as i-line (wavelength of about 365 nm), KrF excimer laser (wavelength of about 248 nm), ArF excimer laser (wavelength of about 193 nm), and/or the like may provide a photoresist pattern 108 having a width of about 5 nm to about 100 nm (per a set, given, and/or suitable thickness). For example, the photoresist pattern 108 may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In one or more embodiments, the photoresist pattern 108 may have a pitch of having a half-pitch of less than or equal to about 50 nm, for example, less than or equal to about 40 nm, less than or equal to about 30 nm, less than or equal to about 20 nm, less than or equal to about 15 nm, or less than or equal to about 10 nm, and a line width roughness of less than or equal to about 10 nm, less than or equal to about 5 nm, less than or equal to about 3 nm, or less than or equal to about 2 nm.

Subsequently, the photoresist pattern 108 is utilized as an etching mask to etch the resist underlayer 104. Through this etching process, an organic layer pattern 112 is formed. The organic layer pattern 112 also may have a width corresponding to that of the photoresist pattern 108.

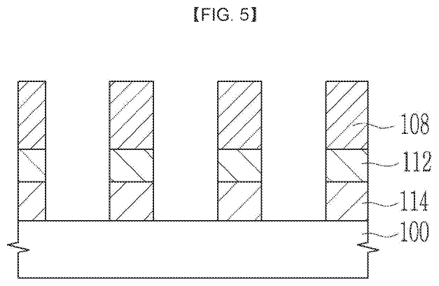

Referring to FIG. 5, the photoresist pattern 108 is applied as an etching mask to etch the exposed thin film 102. As a result, the thin film is formed with a thin film pattern 114.

The etching of the thin film 102 may be, for example, dry etching utilizing an etching gas, and the etching gas may be, for example, CHF₃, CF₄, Cl₂, BCl₃, and/or a mixed gas thereof.

In the exposure process, the thin film pattern 114 formed by utilizing the photoresist pattern 108 formed through the exposure process performed by utilizing an EUV light source may have a width corresponding to that of the photoresist pattern 108. For example, the thin film pattern 114 may have a width of about 5 nm to about 100 nm which is equal or substantially equal to that of the photoresist pattern 108. For example, the thin film pattern 114 formed by utilizing the photoresist pattern 108 formed through the exposure process performed by utilizing an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and in some embodiments, less than or equal to about 20 nm, like, substantially similar to that of the photoresist pattern 108.

Hereinafter, the present disclosure will be described in more detail through examples of the preparation of the aforementioned semiconductor photoresist composition. However, embodiments of the present disclosure are technically not restricted by the following examples.

### Synthesis of Organotin Compound

### Synthesis Example 1

In a 250 mL 2-necked round-bottomed flask, pyruvic acid (7.92 g, 90 mmol) was added, and 100 mL of H₂O was added thereto. Subsequently, hydroxylamine hydrochloride (6.25 g, 90 mmol) was slowly added thereto in a dropwise fashion at room temperature, and sequentially, ammonium bicarbonate (14.22 g, 180 mmol) was slowly added thereto in a dropwise fashion and then, stirred for 2 hours. Then, butyltin trichloride (8.46 g, 30 mmol) was added thereto in a dropwise fashion at room temperature and then, stirred for 4 hours. A resultant therefrom was filtered under a reduced pressure and then, several times washed with ice cold H₂O, and vacuum-dried at room temperature, obtaining a compound represented by Chemical Formula 4.

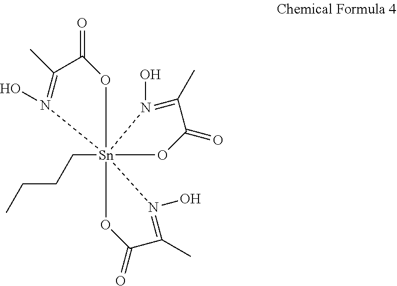

### Synthesis Example 2

A compound represented by Chemical Formula 5 was obtained in substantially the same manner as in Synthesis Example 1 except that phenyl pyruvate (14.77 g, 90 mmol) was utilized instead of the pyruvic acid (7.92 g, 90 mmol).

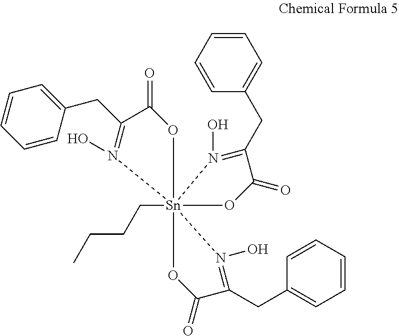

### Synthesis Example 3

A compound represented by Chemical Formula 6 was obtained in substantially the same manner as in Synthesis Example 1 except that 2-(methoxyimino)propanoic acid (10.54 g, 90 mmol) was utilized instead of the pyruvic acid (7.92 g, 90 mmol).

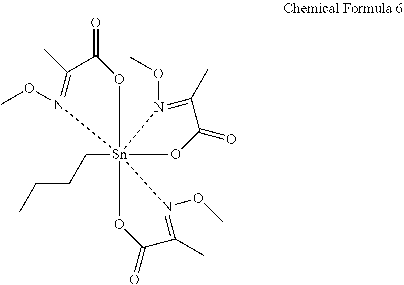

### Comparative Synthesis Example 1

In a 100 mL round-bottomed flask, iPrSnPh₃ (25.44 mmol, 10 g) and acetic acid (76.31 mmol, 4.6 g) were dissolved in 35 mL of acetonitrile and then, heated under reflux for 24 hours. Subsequently, a resultant therefrom was vacuum-dried to completely remove the solvent, obtaining a compound represented by Chemical Formula 7.

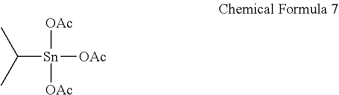 [SMILES: CC(=O)[O][Sn]([O]C(C)=O)([O]C(C)=O)[CH](C)C]

### Comparative Synthesis Example 2

In a 100 mL round-bottomed flask, LiNMe₂ (102.03 mmol, 5.2 g) was dissolved in anhydrous hexane, and then, the flask was cooed to −78° C. Subsequently, isopropyltin trichloride (34.01 mmol, 10 g) was slowly added thereto in a dropwise fashion and then, reacted at room temperature for 24 hours. When a reaction was completed, a resultant therefrom was filtered, concentrated, and vacuum-dried, obtaining a compound represented by Chemical Formula 8.

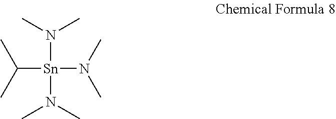

### Examples 1 to 3 and Comparative Examples 1 and 2: Preparation of Semiconductor Photoresist Compositions

The compounds according to Synthesis Examples 1 to 3 and Comparative Synthesis Examples 1 and 2 were respectively dissolved in 4-methyl-2-pentanol at a concentration of 3 wt % and then, filtered with a 0.1 μm PTFE syringe filter, preparing a photoresist composition.

### Formation of Photoresist Layer

A circular silicon wafer with a native-oxide surface and a diameter of 4 inches was utilized as a substrate for depositing a thin film, and before depositing the thin film, the wafer was treated in a UV ozone cleaning system for 10 minutes. Each of the semiconductor photoresist compositions of Examples 1 to 3 and Comparative Examples 1 and 2 was spin-coated on the corresponding treated substrate at 1500 rpm for 30 seconds and post-apply baked (PAB) at 100° C. for 120 seconds, forming the thin film.

Subsequently, as a result of measuring a thickness of each of the thin films after coating and baking through ellipsometry, Examples 1 to 3 each exhibited 25 nm, and Comparative Examples 1 and 2 each exhibited 20 nm.

### Evaluation 1: Evaluation of Coating Properties

The photoresist layers formed in the coating method according to Examples 1 to 3 and Comparative Examples 1 and 2 were each measured with respect to surface roughness (Rq) through AFM (atomic force microscopy), and the results according to the following evaluation criteria are provided in Table 1.

### Evaluation Criteria

∘: less than or equal to 0.5 nm
Δ: greater than 0.5 nm and less than 1 nm
X: greater than 1 nm

### Evaluation 2: Evaluation of Storage Stability

The photoresist compositions of Examples 1 to 3 and Comparative Examples 1 and 2 were each measured with respect to initial sensitivity, and a precipitation degree was evaluated into 3 steps by checking them with naked eyes, after allowed to stand at room temperature (0° C. to 30° C.) and setting storability criteria as follows.

### Storage Criteria

∘: can be stored for 3 months or more
Δ: can be stored for more than or equal to 2 weeks and less than 3 months
X: can be stored for less than 2 weeks

TABLE 1

| | Coating | Storage |
|---|---|---|
| | properties | stability |
| Example 1 | ◯ | ◯ |
| Example 2 | ◯ | ◯ |
| Example 3 | ◯ | ◯ |
| Comparative Example 1 | Δ | Δ |
| Comparative Example 2 | X | X |

Referring to the results of Table 1, the photoresist compositions for a semiconductor according to Examples 1 to 3 each exhibited excellent or suitable coating properties and storage stability, and patterns formed therefrom were expected exhibit excellent or suitable sensitivity without greatly increasing line edge roughness, compared with those of Comparative Examples 1 and 2.

As utilized herein, the terms “and/or” and “or” may include any and all combinations of one or more of the associated listed items. Expressions such as “at least one of,” when preceding a list of elements, modify the entire list of elements and do not modify the individual elements of the list.

It will be further understood that the terms “comprise”, “include,” or “have/has,” when utilized in the present disclosure, specify the presence of stated features, integers, steps, operations, elements, and/or components, but do not preclude the presence or addition of one or more other features, integers, steps, operations, elements, components, and/or groups thereof. The “/” utilized below may be interpreted as “and” or as “or” depending on the situation.

As utilized herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure”.

As utilized herein, the term “about,” or similar terms are used as terms of approximation and not as terms of degree, and are intended to account for the inherent deviations in measured or calculated values that would be recognized by those of ordinary skill in the art.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Hereinbefore, the certain embodiments of the present disclosure have been described and illustrated, however, it is apparent to a person with ordinary skill in the art that the present disclosure is not limited to the embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure and equivalents thereof.

Reference Numerals

| | |
|---|---|
| 100: substrate | 102: thin film |
| 104: resist underlayer | 106: photoresist layer |
| 106a: non-exposed region | 106b: exposed region |
| 108: photoresist pattern | 112: organic layer pattern |
| 114: thin film pattern | |

What is claimed is:

1. A photoresist composition, comprising
an organotin compound represented by Chemical Formula 1; and
a solvent: 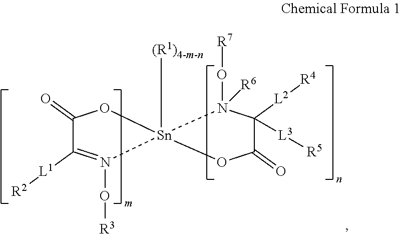
wherein, in Chemical Formula 1,
R¹ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof,
R², R⁴, and R⁵ are each independently hydrogen, a cyano group, a sulfonyl group, a thiol group, a sulfide group, a thioketone group, a ketone group, an aldehyde group, a hydroxy group, an amine group, an amide group, a halogen, a substituted or unsubstituted C1 to C20 alkyl group, a substituted or unsubstituted C1 to C20 alkoxy group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, a substituted or unsubstituted C2 to C30 heterocyclic group, or a combination thereof,
R³, R⁶, and R⁷ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof,
L¹ to L³ are each independently
a single bond,
a substituted or unsubstituted divalent C1 to C20 saturated aliphatic hydrocarbon group,
a substituted or unsubstituted divalent C3 to C20 saturated or unsaturated alicyclic hydrocarbon group,
a substituted or unsubstituted divalent C2 to C20 unsaturated aliphatic hydrocarbon group comprising at least one of a double bond or a triple bond,
a substituted or unsubstituted divalent C6 to C20 aromatic hydrocarbon group,
—C(═O)—,
—C(═S)—, or
a combination thereof,
m and n are each independently one of integers from 0 to 3, and
m+n is an integer of greater than or equal to 1.

2. The photoresist composition of claim 1, wherein
Chemical Formula 1 is represented by Chemical Formula 2 or Chemical Formula 3: 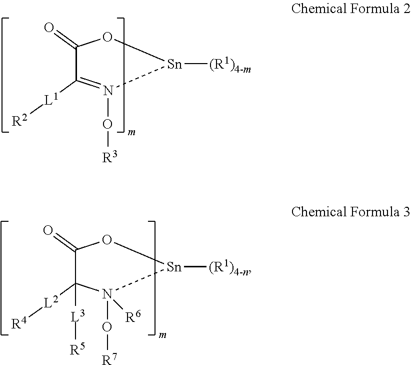
and
wherein, in Chemical Formula 2 and Chemical Formula 3,
R¹ to R⁷ and L¹ to L³ are each the same as defined in Chemical Formula 1, and
m and n are each independently one of integers from 1 to 3.

3. The photoresist composition of claim 2, wherein
m and n are each independently an integer of 1 or 2.

4. The photoresist composition of claim 2, wherein
Chemical Formula 2 is represented by Chemical Formula 2-1: 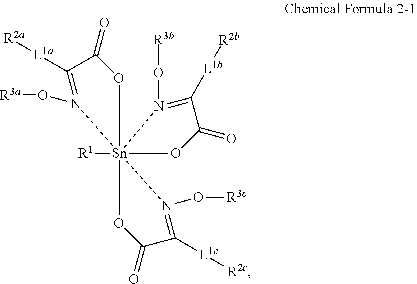
and
wherein, in Chemical Formula 2-1,
R¹ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof,
R^{2a}, R^{2b}, and R^{2c} are each independently hydrogen, a cyano group, a sulfonyl group, a thiol group, a sulfide group, a thioketone group, a ketone group, an aldehyde group, a hydroxy group, an amine group, an amide group, a halogen, a substituted or unsubstituted C1 to C20 alkyl group, a substituted or unsubstituted C1 to C20 alkoxy group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, a substituted or unsubstituted C2 to C30 heterocyclic group, or a combination thereof,
R^{3a}, R^{3b}, and R^{3c} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof, and
L¹a, L^{1b}, and L^{1c} are each independently
a single bond,
a substituted or unsubstituted divalent C1 to C20 saturated aliphatic hydrocarbon group,
a substituted or unsubstituted divalent C3 to C20 saturated or unsaturated alicyclic hydrocarbon group,
a substituted or unsubstituted divalent C2 to C20 unsaturated aliphatic hydrocarbon group comprising at least one of a double bond or a triple bond,
a substituted or unsubstituted divalent C6 to C20 aromatic hydrocarbon group,
—C(═O)—,
—C(═S)—, or
a combination thereof.

5. The photoresist composition of claim 2, wherein
Chemical Formula 3 is represented by Chemical Formula 3-1: 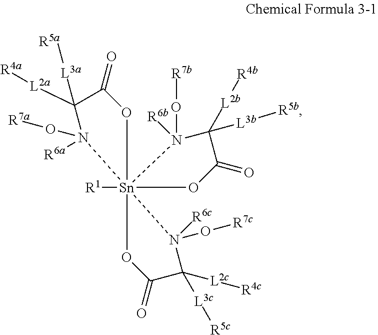
and
wherein, in Chemical Formula 3-1,
R¹ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof,
R^{4a}, R^{4b}, R^{4c}, R^{5a}, R^{5b}, and R^{5c} are each independently hydrogen, a cyano group, a sulfonyl group, a thiol group, a sulfide group, a thioketone group, a ketone group, an aldehyde group, a hydroxy group, an amine group, an amide group, a halogen, a substituted or unsubstituted C1 to C20 alkyl group, a substituted or unsubstituted C1 to C20 alkoxy group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, a substituted or unsubstituted C2 to C30 heterocyclic group, or a combination thereof,
R^{6a}, R^{6b}, R^{6c}, R^{7a}, R^{7b}, and R^{7c} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof, and
L²a, L³a, L²b, L³b, L²c, and L³c are each independently
a single bond,
a substituted or unsubstituted divalent C1 to C20 saturated aliphatic hydrocarbon group,
a substituted or unsubstituted divalent C3 to C20 saturated or unsaturated alicyclic hydrocarbon group,
a substituted or unsubstituted divalent C2 to C20 unsaturated aliphatic hydrocarbon group comprising at least one of a double bond or a triple bond,
a substituted or unsubstituted divalent C6 to C20 aromatic hydrocarbon group,
—C(═O)—,
—C(═S)—, or
a combination thereof.

6. The photoresist composition of claim 1, wherein
R¹ is a substituted or unsubstituted C1 to C20 alkyl group.

7. The photoresist composition of claim 1, wherein
R², R⁴, and R⁵ are each independently hydrogen, a cyano group, a sulfonyl group, a thiol group, a sulfide group, a thioketone group, a ketone group, an aldehyde group, a hydroxy group, an amine group, an amide group, a cyano group, a halogen, a substituted or unsubstituted C1 to C20 alkyl group, a substituted or unsubstituted C6 to C30 aryl group, a substituted or unsubstituted C2 to C30 heterocyclic group, or a combination thereof.

8. The photoresist composition of claim 1, wherein
R², R⁴, and R⁵ are each independently hydrogen, a cyano group, a sulfonyl group, a thiol group, a sulfide group, a thioketone group, a ketone group, an aldehyde group, a hydroxy group, an amine group, an amide group, a halogen, n-propyl group, an n-butyl group, an n-pentyl group, an n-hexyl group, an n-heptyl group, an n-octyl group, an n-nonyl group, an n-decyl group, an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, a tert-decyl group, a substituted or unsubstituted phenyl group, a substituted or unsubstituted benzoxazolyl group, a substituted or unsubstituted thiazolyl group a substituted or unsubstituted benzothiazolyl group, or a substituted or unsubstituted benzimidazolyl group.

9. The photoresist composition of claim 1, wherein
L¹ to L³ are each independently a single bond, or a substituted or unsubstituted C1 to C20 alkylene group.

10. The photoresist composition of claim 1, wherein
the organotin compound is at least one selected from compounds listed in Group 2:

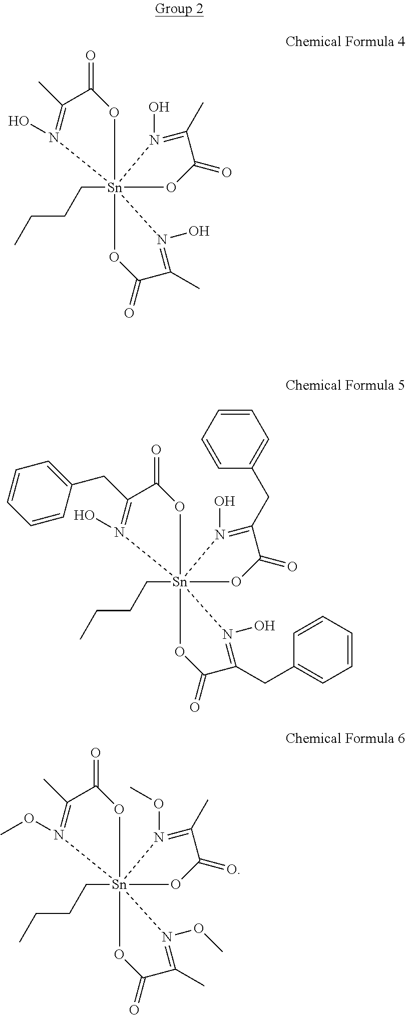

11. The photoresist composition of claim 1, wherein
based on 100 wt % of the photoresist composition, the organotin compound is in an amount of about 1 wt % to about 30 wt %.

12. The photoresist composition of claim 1, wherein
the photoresist composition further comprises, as an additive, a surfactant, a crosslinking agent, a leveling agent, or a combination thereof.

13. A method of forming patterns, the method comprising
providing an etching target layer on a substrate,
coating the photoresist composition of claim 1 on the etching target layer to form a photoresist layer,
patterning the photoresist layer to form a photoresist pattern, and
etching the etching target layer utilizing the photoresist pattern as an etching mask.

14. The method of claim 13, wherein
the photoresist pattern is formed utilizing light in a wavelength of about 5 nm to about 150 nm.

15. The method of claim 13, wherein
the method further comprises providing a resist underlayer formed between the etching target layer and the photoresist layer.

16. The method of claim 13, wherein
the photoresist pattern has a width of about 5 nm to about 100 nm.

17. The method of claim 13, wherein
based on 100 wt % of the photoresist composition, the organotin compound is in an amount of about 1 wt % to about 30 wt %.

18. The method of claim 13, wherein
based on 100 wt % of the photoresist composition, the organotin compound is in an amount of about 1 wt % to about 5 wt %.

19. The method of claim 13, wherein
the photoresist composition further comprises, as an additive, a surfactant, a crosslinking agent, a leveling agent, or a combination thereof.

20. The method of claim 13, wherein
the photoresist layer is formed by a heat treatment at about 80° C. to about 120° C. after the coating of the photoresist composition.
